(19) United States
(12) Patent Application Publication
(10) Pub. No.: US 2020/0280301 A1
(43) Pub. Date: Sep. 3, 2020

(54) MULTIPLEXER

(71) Applicant: Murata Manufacturing Co., Ltd., Nagaokakyo-shi (JP)

(72) Inventor: Yohei KONAKA, Nagaokakyo-shi (JP)

(21) Appl. No.: 16/874,755

(22) Filed: May 15, 2020

Related U.S. Application Data
(63) Continuation of application No. PCT/JP2018/047229, filed on Dec. 21, 2018.

(30) Foreign Application Priority Data
Dec. 25, 2017 (JP) 2017-247488

(51) Int. Cl. H03H 9/56; H03H 9/205; H03H 9/70; H03H 9/13

(52) U.S. Cl. CPC H03H 9/568; H03H 9/13; H03H 9/70; H03H 9/205

(57) ABSTRACT

A multiplexer includes a first filter which is a receive filter using acoustic waves and whose pass band is a first frequency band, a second filter whose pass band is a second frequency band, and a third filter whose pass band is a third frequency band. The first filter includes a ladder circuit including serial arm resonators and multiple parallel arm circuits. A parallel arm resonator is included in at least one of the multiple parallel arm circuits except the parallel arm circuit. The parallel arm circuit is connected at the position closest to a common terminal. At least one of the frequencies expressed by ±M×f1±N×f2 is included in the third frequency band, and the resonant frequency of the parallel arm resonator is included in the third frequency band.

### CROSS REFERENCE TO RELATED APPLICATIONS

This application claims the benefit of priority to Japanese Patent Application No. 2017-247488 filed on Dec. 25, 2017 and is a Continuation Application of PCT Application No. PCT/JP2018/047229 filed on Dec. 21, 2018. The entire contents of each application are hereby incorporated herein by reference.

### BACKGROUND OF THE INVENTION

### 1. Field of the Invention

The present invention relates to a multiplexer including an acoustic wave filter.

### 2. Description of the Related Art

Recently, multiplexers (band separators or the like) including acoustic wave filters have been used widely in communication devices.

Such a multiplexer includes, for example, a receive filter and a transmit filter. For example, when the frequency of a receive signal, which is handled in the communication device, is represented by Rx and the frequency of a transmit signal is represented by Tx, an antenna included in a communication device also receives interfering waves including a frequency (for example, Rx−Tx, Rx+Tx, 2Tx−Rx, or 2Tx+Rx) different from Rx or Tx. In an acoustic wave filter included in the multiplexer, intermodulation distortion (IMD) easily occurs due to non-linearity of an acoustic wave resonator included in the acoustic wave filter. That is, when the antenna receives the interfering waves, IMD having a frequency equal or substantially equal to that of the receive signal occurs due to intermodulation with the transmit signal. There is a problem that influence from the IMD causes the SN (Signal Noise) ratio of the receive signal to be reduced.

To address the problem, the following technique is disclosed (for example, Japanese Unexamined Patent Application Publication No. 2014-013959). In a multiplexer (for example, a duplexer) including a transmit filter and a receive filter, the parallel arm, which is positioned closest to the antenna, in the receive filter is connected to a parallel arm resonator that attenuates the interfering waves. This causes the interfering waves to be attenuated, achieving reduction of the IMD.

However, to provide a multiplexer compatible with more frequency bands, the duplexer of the related art may have a configuration in which a different filter having a further different pass band is connected through a common connection. At that time, when the frequency included in the interfering waves is included in the pass band of the different filter, there arises a problem that the insertion loss in the pass band of the different filter degrades. This is because, although the parallel arm resonator that attenuates the interfering waves achieves reduction of the IMD, the parallel arm resonator has a resonance point which is positioned in the pass band of the different filter and which thus affects the bandpass characteristics of the different filter.

### SUMMARY OF THE INVENTION

Preferred embodiments of the present invention provide multiplexers each of which, while providing a reduction of the IMD in the pass band of a receive filter, are able to significantly reduce or prevent degradation of the insertion loss of a different filter which is electrically connected to the receive filter through a common connection.

A multiplexer according to a preferred embodiment of the present invention includes a common terminal, a first terminal, a second terminal, a third terminal, a first filter, a second filter, and a third filter. The first filter is a receive filter which is provided on a first path electrically connecting the common terminal to the first terminal and which uses an acoustic wave whose pass band is a first frequency band. The second filter is provided on a second path electrically connecting the common terminal to the second terminal, and has a pass band which is a second frequency band. The third filter is provided on a third path electrically connecting the common terminal to the third terminal, and has a pass band which is a third frequency band. The first frequency band, the second frequency band, and the third frequency band are bands whose center frequencies are different from each other. The first filter includes a ladder circuit including at least one serial arm resonator provided on the first path and a plurality of parallel arm circuits provided between the ground and corresponding connection nodes which are provided on the first path and which are different from each other. At least one of the plurality of parallel arm circuits except a closest parallel arm circuit includes a first parallel arm resonator. The closest parallel arm circuit is connected at a position closest to the common terminal. At least one of frequencies expressed by ±M×f1±N×f2 is included in the third frequency band where N and M are natural numbers equal to or more than one, f1 represents a frequency included in the first frequency band, and f2 represents a frequency included in the second frequency band. The resonant frequency of the first parallel arm resonator is included in the third frequency band.

The parallel arm circuit, which is among the parallel arm circuits included in the first filter and which is connected at the position closest to the common terminal, easily affects the return loss of the first filter, that is, easily increases the return loss. Assume the case in which, as described in Japanese Unexamined Patent Application Publication No. 2014-013959, the first parallel arm resonator that attenuates the interfering wave, whose frequency is ±M×f1±N×f2, is included in the parallel arm circuit connected closest to the antenna side (that is, at the position closest to the common terminal). This causes degradation of the insertion loss in the pass band of the third filter which is electrically connected to the first filter through a common connection and whose pass band includes the resonant frequency of the first parallel arm resonator.

In contrast, according to a preferred embodiment of the present invention, the first filter includes the first parallel arm resonator in at least one of the multiple parallel arm circuits except the parallel arm circuit that is connected at the position closest to the common terminal. Thus, the first parallel arm resonator does not substantially affect the return loss of the first filter, thus providing significant reduction or prevention of degradation of the insertion loss in the pass band of the third filter electrically connected to the first filter through a common connection. The first filter, which includes the first parallel arm resonator described above, provides attenuation of the interfering wave and reduction of the IMD. Therefore, while the IMD in the pass band of the receive filter (first filter) is reduced, the degradation of the insertion loss in the passband of the different filter (third filter), which is electrically connected to the receive filter through a common connection, may be significantly reduced or prevented.

The resonant frequency of the first parallel arm resonator may be at least one of the frequencies expressed by ±M×f1±N×f2.

Accordingly, the first parallel arm resonator is able to attenuate the interfering wave whose frequency is ±M×f1±N×f2.

The first parallel arm resonator may be included in a parallel arm circuit connected at a position second closest to the common terminal among the plurality of parallel arm circuits.

Accordingly, a reduction of the IMD is provided in the serial arm resonators and the parallel arm circuits which are electrically connected after the parallel arm circuit connected at a position second closest to the common terminal, when viewed from the common terminal. That is, the IMD in as many resonators as possible may be reduced. Therefore, effective reduction of the IMD in the pass band of the receive filter is able to be provided.

The second filter may be a transmit filter, and the first filter and the second filter may define a duplexer.

Accordingly, a reduction of the IMD occurring due to intermodulation between a transmit signal, which passes through the second filter, and the interfering wave whose frequency is ±M×f1±N×f2 is provided.

The first frequency band may be about 2110 MHz to about 2170 MHz, the second frequency band may be about 1920 MHz to about 1980 MHz, and the third frequency band may be about 1710 MHz to about 1785 MHz.

Accordingly, the following advantageous effects are provided at the same time, at least when multi-band transmission is implemented among Band1Rx (about 2110 MHz-about 2170 MHz), Band1Tx (about 1920 MHz-about 1980 MHz), and Band3Tx (about 1710 MHz-about 1785 MHz) in LTE (Long Term Evolution): reduction of the IMD in the pass band of the first filter whose pass band is Band1Rx; and significant reduction or prevention of the degradation of the insertion loss in the pass band of the third filter whose pass band is Band3Tx.

The multiplexers according to preferred embodiments of the present invention each provide reduction of the IMD in the pass band of the receive filter and significant reduction or prevention of the degradation of the insertion loss at the same time.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a diagram showing an exemplary multiplexer according to a preferred embodiment of the present invention.

FIG. 2 is a diagram showing the circuitry of an exemplary first filter according to a preferred embodiment of the present invention.

FIG. 3 is a diagram showing the circuitry of an exemplary first filter according to an example of the related art.

FIG. 4 is a diagram showing the circuitry of an exemplary first filter according to a comparative example.

FIG. 5A is a graph showing bandpass characteristics of first filters of a comparative example and an example of the related art.

FIG. 5B is a graph showing bandpass characteristics of second filters of a comparative example and an example of the related art.

FIG. 5C is a graph showing bandpass characteristics of third filters of a comparative example and an example of the related art.

FIG. 5D is a graph showing bandpass characteristics of fourth filters of a comparative example and an example of the related art.

FIG. 6 is a diagram showing an example of return loss in a first filter.

FIG. 7 is a diagram showing another example of return loss in a first filter.

FIG. 8A is a graph showing bandpass characteristics of first filters of a preferred embodiment of the present invention and an example of the related art.

FIG. 8B is graph showing bandpass characteristics of second filters of a preferred embodiment of the present invention and an example of the related art.

FIG. 8C is a graph showing bandpass characteristics of third filters of a preferred embodiment of the present invention and an example of the related art.

FIG. 8D is a graph showing bandpass characteristics of fourth filters of a preferred embodiment of the present invention and an example of the related art.

FIG. 9 is a diagram showing IMD characteristics of resonators in first filters of a preferred embodiment of the present invention and an example of the related art.

### DETAILED DESCRIPTION OF THE PREFERRED EMBODIMENTS

Preferred embodiments of the present invention will be described in detail below with reference to the drawings. The preferred embodiments described below provide comprehensive or concrete examples. The numeric values, shapes, materials, components, component arrangement and connections, and the like, which are indicated by the preferred embodiment below, are exemplary, and are not intended to limit the present invention. Among components in the preferred embodiments below, components which are not described in the independent claim are described as optional components. In the figures, identical reference numerals are designated for the same or substantially the same features and elements. Repeated description may be avoided or simplified. In the preferred embodiments below, “to connect” encompasses not only direct connection but also electrical connection through a different device and the like.

### 1. Configuration of a Multiplexer

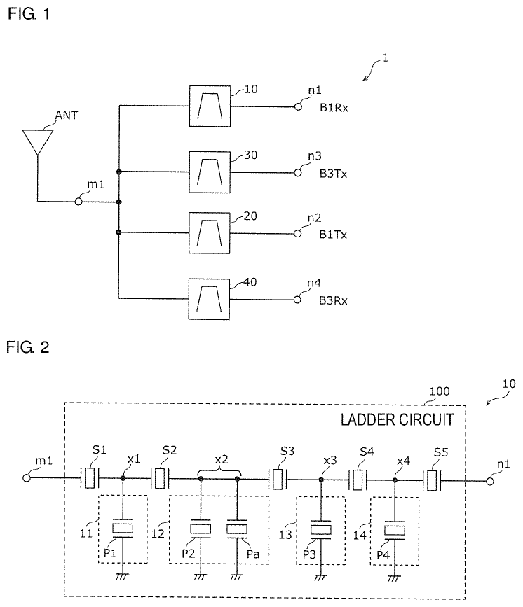

A multiplexer according to a preferred embodiment of the present invention will be described with respect to FIG. 1.

FIG. 1 is a diagram showing an exemplary multiplexer 1 according to the present preferred embodiment. FIG. 1 also shows an antenna device ANT connected to a common terminal m1 of the multiplexer 1. The antenna device ANT is a multi-band antenna which is in conformity with a communication standard, for example, LTE and which receives/transmits radio frequency signals.

The multiplexer 1 is a circuit which separates/combines waves and which includes an acoustic wave filter. In the present preferred embodiment, the multiplexer 1 is a quadplexer. The multiplexer 1 includes, as input/output terminals, the common terminal m1, an input/output terminal n1 (first terminal), an input/output terminal n2 (second terminal), an input/output terminal n3 (third terminal), and an input/output terminal n4. The multiplexer 1 includes a first filter 10, a second filter 20, a third filter 30, and a fourth filter 40, each of which includes one side (the side different from the side adjacent to or in a vicinity of to the corresponding one of the input/output terminals n1 to n4) which is connected to the common terminal m1 defining and functioning as a common connection.

The first filter 10 is a receive filter which is provided on a first path connecting the common terminal m1 to the input/output terminal n1 and which uses acoustic waves whose pass band is a first frequency band. In this example, the first frequency band is preferably, for example, Band1Rx (about 2110 MHz-about 2170 MHz) of LTE.

The second filter 20 is a filter which is provided on a second path connecting the common terminal m1 to the input/output terminal n2 and whose pass band is a second frequency band. In this example, the second filter 20 is a transmit filter. The second frequency band is preferably, for example, Band1Tx (about 1920 MHz-about 1980 MHz) of LTE. When the first filter 10 and the second filter 20 are focused on in the multiplexer 1, the first filter 10 and the second filter 20 define a duplexer.

The third filter 30 is a filter which is provided on a third path connecting the common terminal m1 to the input/output terminal n3 and whose pass band is a third frequency band. In this example, the third filter 30 is a transmit filter. The third frequency band is preferably, for example, Band3Tx (about 1710 MHz-about 1785 MHz) of LTE.

The fourth filter 40 is a filter which is provided on a fourth path connecting the common terminal m1 to the input/output terminal n4 and whose pass band is a fourth frequency band. In this example, the fourth filter 40 is a receive filter. The fourth frequency band is preferably, for example, Band3Rx (about 1805 MHz-about 1880 MHz) of LTE.

Thus, the first frequency band, the second frequency band, the third frequency band, and the fourth frequency band are bands different from each other. The single multiplexer 1 is compatible with multiple frequency bands.

The first filter 10 is an acoustic wave filter. The type of the second filter 20, the third filter 30, and the fourth filter 40 is not particularly limiting. For example, the filters are not limited to acoustic wave filters, and may be LC filters. In addition, the second filter 20 may be a receive filter; the third filter 30 may be a receive filter; the fourth filter 40 may be a transmit filter.

### 2. Configuration of the First Filter

The first filter 10 according to the present preferred embodiment will be described, and an example of the related art and a comparative example will be also described.

The first filter 10 of the present preferred embodiment (hereinafter also referred to as a preferred embodiment example) will be described with respect to FIG. 2.

FIG. 2 is a diagram showing the circuitry of an exemplary first filter 10 according to the preferred embodiment example.

The first filter 10 includes a ladder circuit 100 which includes at least one serial arm resonator provided on the first path connecting the common terminal m1 to the input/output terminal n1, and which also includes multiple parallel arm circuits provided between the ground and the respective connection nodes that are different from each other and that are provided on the first path. Each connection node is a connection point between devices or between a device and a terminal. FIG. 2 shows the connection points as points indicated by x1 and the like. Each parallel arm circuit is a circuit including at least one parallel arm resonator.

The first filter 10 includes, as the at least one serial arm resonator, serial arm resonators S1 to S5 connected to each other in series. The first filter 10 includes, as the multiple parallel arm circuits, a parallel arm circuit 11, a parallel arm circuit 12, a parallel arm circuit 13, and a parallel arm circuit 14. The parallel arm circuit 11 is connected between the ground and the connection node x1 between the serial arm resonators S1 and S2. The parallel arm circuit 12 is connected between the ground and a connection node x2 between the serial arm resonators S2 and S3. The parallel arm circuit 13 is connected between the ground and a connection node x3 between the serial arm resonators S3 and S4. The parallel arm circuit 14 is connected between the ground and a connection node x4 between the serial arm resonators S4 and S5. The ladder circuit 100 includes the serial arm resonators S1 to S5 and the parallel arm circuits 11 to 14. The parallel arm circuit 11 includes a parallel arm resonator P1 connected between the connection node x1 and the ground. The parallel arm circuit 12 includes a parallel arm resonator P2 and a parallel arm resonator Pa which are connected between the identical connection node x2 and the ground. The parallel arm circuit 13 includes a parallel arm resonator P3 connected between the connection node x3 and the ground. The parallel arm circuit 14 includes a parallel arm resonator P4 connected between the connection node x4 and the ground. The connection node x2 may be a single point on the path. Alternatively, when, as shown in FIG. 2, two different points are provided on the path and are positioned without a resonator or a device provided between the points, the two points have the same or substantially the same potential. Thus, the two points may be interpreted as “the identical connection node”. Therefore, in this example, the parallel arm resonator P2 and the parallel arm resonator Pa are connected in parallel between the identical connection node x2 and the ground.

The parallel arm resonator Pa is a first parallel arm resonator that attenuates interfering waves and that is included in at least one of the parallel arm circuits 11 to 14 except the parallel arm circuit 11 connected at the position closest to the common terminal m1. In the present preferred embodiment example, the parallel arm resonator Pa is included in the parallel arm circuit 12 connected at the position second closest to the common terminal m1 among the parallel arm circuits 11 to 14. The parallel arm resonator Pa is not necessarily included in the parallel arm circuit 12, and may be included in the parallel arm circuit 13 or 14 connected at a close position after the second position starting from the common terminal m1. The parallel arm resonator Pa may be included in two or more parallel arm circuits among the parallel arm circuits 12 to 14. The parallel arm circuits 11 to 14 may include other parallel arm resonator or an impedance element, for example, a capacitor or an inductor.

The at least one serial arm resonator and the parallel arm resonators included in the parallel arm circuits are resonators using acoustic waves, and are preferably, for example, resonators using SAWs (Surface Acoustic Waves), resonators using BAWs (Bulk Acoustic Waves), or FBARs (Film Bulk Acoustic Resonators). The SAWs include not only surface acoustic waves but also boundary waves. In this example, these resonators are SAW resonators. Thus, the first filter 10 may include IDT (Inter Digital Transducer) electrodes provided on a substrate having piezoelectricity, thus providing a small and low-profile filter circuit having very steep bandpass characteristics. The substrate having piezoelectricity is a substrate having piezoelectricity at least on its surface. The substrate may include, for example, a piezoelectric thin film on its surface, and may include a multilayer body which includes a film having an acoustic velocity different from that of the piezoelectric thin film, a support substrate, and the like. Alternatively, the substrate may be, for example, one of the following multilayer bodies: a multilayer body having a high-acoustic-velocity support substrate and a piezoelectric thin film provided on the high-acoustic-velocity support substrate; a multilayer body having a high-acoustic-velocity support substrate, a low-acoustic-velocity film provided on the high-acoustic-velocity support substrate, and a piezoelectric thin film provided on the low-acoustic-velocity film; a multilayer body having a support substrate, a high-acoustic-velocity film provided on the support substrate, a low-acoustic-velocity film provided on the high-acoustic-velocity film, and a piezoelectric thin film provided on the low-acoustic-velocity film. The substrate may have piezoelectricity in the entire substrate. The same or similar features are applied to resonators described below, and detailed descriptions will not be reiterated.

The serial arm resonators S1 to S5 and the parallel arm resonators P1 to P4 are resonators defining the pass band of the first filter 10. Specifically, the resonant frequencies of the serial arm resonators S1 to S5 and the anti-resonant frequencies of the parallel arm resonators P1 to P4 are positioned at or near the center frequency of the pass band of the first filter 10. The anti-resonant frequencies of the serial arm resonators S1 to S5 are positioned at an attenuation pole in a vicinity of the high frequency side of the pass band. The resonant frequencies of the parallel arm resonators P1 to P4 are positioned at an attenuation pole in a vicinity of the low frequency side of the pass band. Thus, the pass band is provided.

In contrast, the parallel arm resonator Pa does not contribute to defining of the pass band. The parallel arm resonator Pa will be described below.

The multiplexer 1 includes, for example, the first filter 10 as a receive filter and the second filter 20 as a transmit filter. For example, a frequency included in the first frequency band (the pass band of the first filter 10) handled by a communication device including the multiplexer 1 is represented by f1; a frequency included in the second frequency band (the pass band of the second filter 20) is represented by f2. The common terminal m1 also receives interfering waves whose frequency (for example, at least one of the frequencies expressed by ±M×f1±N×f2, where N and M are natural numbers equal to or more than one) is different from f1 or f2. The combination of ±M×f1±N×f2 includes M×f1+N×f2, M×f1−N×f2, −M×f1+N×f2, and −M×f1−N×f2. For example, if the first filter 10 does not include the parallel arm resonator Pa, non-linearity of the acoustic wave resonators included in the first filter 10 easily produces the IMD. That is, when the common terminal m1 receives the interfering waves described above, intermodulation with a transmit signal passing through the second filter 20 produces the IMD at the frequency which is the same or substantially the same as that of a receive signal passing through a filter having the features and elements described above.

In contrast, the parallel arm resonator Pa attenuates the interfering waves received by the common terminal m1. Specifically, the resonant frequency of the parallel arm resonator Pa is the same or substantially the same as any one of the frequencies, ±M×f1±N×f2, of the interfering waves. Thus, the parallel arm resonator Pa attenuates the interfering waves. Accordingly, the IMD in the pass band of the first filter 10 is able to be reduced.

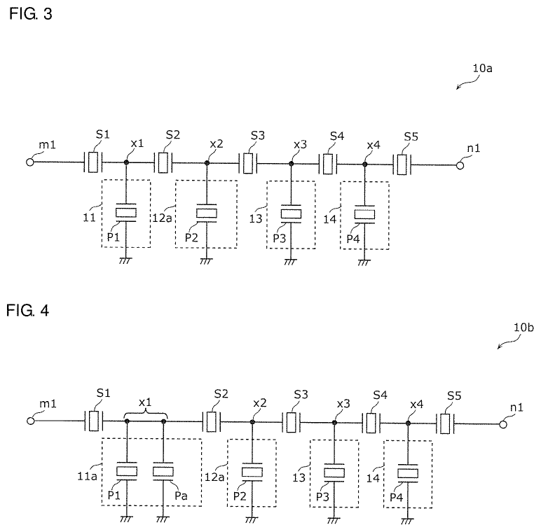

A first filter in an example of the related art will be described with respect to FIG. 3.

FIG. 3 is a diagram showing the circuitry of an exemplary first filter 10a according to the example of the related art.

The first filter 10a is different from the first filter 10 according to the preferred embodiment example in that the first filter 10a includes a parallel arm circuit 12a instead of the parallel arm circuit 12. The other points are the same or substantially the same as those of the first filter 10, and will not be described. The parallel arm circuit 12a does not include the parallel arm resonator Pa connected between the connection node x2 and the ground, and includes the parallel arm resonator P2. As in the first filter 10, the first filter 10a includes the serial arm resonators S1 to S5 and the parallel arm resonators P1 to P4. Thus, the first filter 10a has a pass band which is the first frequency band.

A multiplexer, which includes the first filter 10a, the second filter 20, the third filter 30, and the fourth filter 40, according to the example of the related art is different from the multiplexer 1 in that the multiplexer includes the first filter 10a instead of the first filter 10.

A first filter of a comparative example will be described with respect to FIG. 4.

FIG. 4 is a diagram showing the circuitry of an exemplary first filter 10b according to the comparative example.

The first filter 10b is different from the first filter 10a according to the example of the related art in that the first filter 10b includes a parallel arm circuit 11a instead of the parallel arm circuit 11. The other points are the same or substantially the same as those of the first filter 10a, and will not be described. The parallel arm circuit 11a includes the parallel arm resonator P1 and the parallel arm resonator Pa which are connected between the identical connection node x1 and the ground. In the preferred embodiment example, the parallel arm resonator Pa is included in at least one of the parallel arm circuits 11 to 14 except the parallel arm circuit 11 which is connected at the position closest to the common terminal m1. In the comparative example, the parallel arm resonator Pa is included in the parallel arm circuit 11a connected at the position closest to the common terminal m1 among the parallel arm circuits 11a, 12a, 13, and 14. As in the first filter 10, the first filter 10b includes a portion other than the parallel arm resonator Pa, which includes the serial arm resonators S1 to S5 and the parallel arm resonators P1 to P4. Thus, the first filter 10b has a pass band which is the first frequency band.

A multiplexer, which includes the first filter 10b, the second filter 20, the third filter 30, and the fourth filter 40, according to the comparative example is different from the multiplexer 1 in that the multiplexer includes the first filter 10b instead of the first filter 10.

### 3. Comparison Between the Example of the Related Art and the Comparative Example

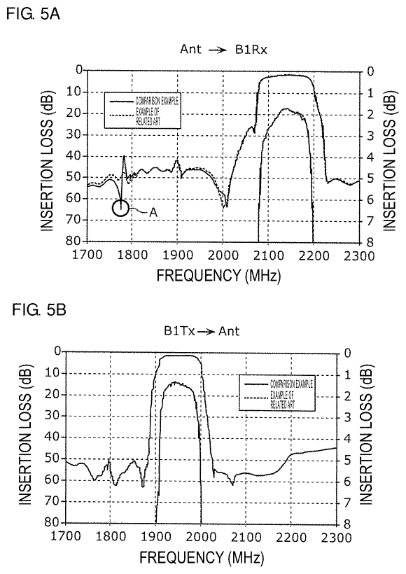

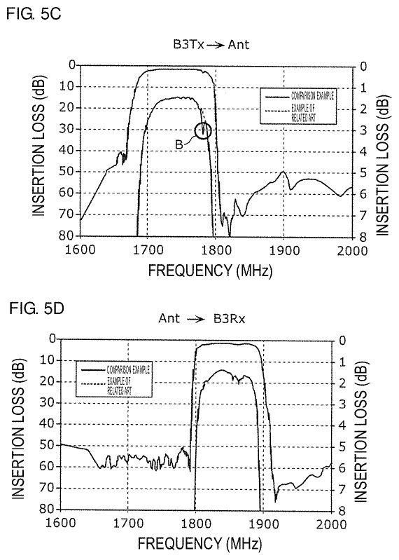

A problem which is present in the comparative example will be described with respect to FIGS. 5A to 5D, 6, and 7 by comparing the example of the related art with the comparative example.

FIG. 5A is a graph showing bandpass characteristics of the first filters 10a and 10b of the comparative example and the example of the related art. FIG. 5B is a graph showing bandpass characteristics of the second filters 20 of the comparative example and the example of the related art. FIG. 5C is a graph showing bandpass characteristics of the third filters 30 of the comparative example and the example of the related art. FIG. 5D is a graph showing bandpass characteristics of the fourth filters 40 of the comparative example and the example of the related art. FIGS. 5A to 5D show the bandpass characteristics of the comparative example with solid lines, and show the bandpass characteristics of the example of the related art with broken lines.

FIG. 5A shows bandpass characteristics in and around the first frequency band (Band1Rx: about 2110 MHz-about 2170 MHz) as bandpass characteristics of the first filter 10b of the comparative example and the first filter 10a of the example of the related art. FIG. 5A shows that, in portion A shown in FIG. 5A, the insertion loss of the comparative example is larger than that of the example of the related art. This is because, as described above, to attenuate the interfering waves whose frequency is ±M×f1±N×f2 (for example, 2×f2−f1), the parallel arm resonator Pa, whose resonant frequency is equal or substantially equal to the frequency of the interfering waves, is included in the parallel arm circuit 11a connected at the position closest to the common terminal m1. The resonant frequency corresponds to portion A shown in FIG. 5A. This causes the interfering waves to be attenuated (not shown), thus providing reduction of the IMD, which occurs due to intermodulation between a transmit signal passing through the second filter 20 and the interfering waves, in the pass band of the first filter 10b.

FIG. 5B shows bandpass characteristics in and around the second frequency band (Band1Tx: about 1920 MHz-about 1980 MHz) as bandpass characteristics of the second filters 20. FIG. 5B shows that there is no difference in the bandpass characteristics of the second filter 20 between the comparative example and the example of the related art.

FIG. 5C shows bandpass characteristics in and around the third frequency band (Band3Tx: about 1710 MHz-about 1785 MHz) as bandpass characteristics of the third filters 30. FIG. 5C shows that, in portion B shown in FIG. 5C, the insertion loss of the comparative example is larger than that of the example of the related art. This is because at least one (for example, 2×f2−f1) of the frequencies, which are expressed by ±M×f1±N×f2, of the interfering waves is included in the third frequency band which is the pass band of the third filter 30, and the resonant frequency of the parallel arm resonator Pa is included in the third frequency band. Such a state occurs, for example, when a multiplexer, which is compatible with Band1Rx, Band3Tx, and Band1Tx, is provided. This causes the parallel arm resonator Pa to increase the return loss, which is viewed from the common terminal m1, of the first filter 10b in the third frequency band (portion A in FIG. 5A), resulting in degradation in the insertion loss in the pass band (third frequency band) of the third filter 30 which is connected to the first filter 10b through the common terminal m1 (portion B in FIG. 5C).

FIG. 5D shows bandpass characteristics in and around the fourth frequency band (Band3Rx: about 1805 MHz-about 1880 MHz) as bandpass characteristic of the fourth filters 40. FIG. 5D shows that there is no or very little difference in bandpass characteristics of the fourth filter 40 between the comparative example and the example of the related art.

For example, if the multiplexer of the comparative example does not include the third filter 30, there are no objects affected by the resonant frequency of the parallel arm resonator Pa, resulting in no problems. However, recently, in addition to the first filter 10b and the second filter 20, the third filter 30 having a pass band different from these pass bands is included to provide compatibility with more frequency bands. Thus, this problem arises.

The principle of degradation of insertion loss in the pass band of the third filter 30 due to the parallel arm resonator Pa included in the parallel arm circuit 11a connected at the position closest to the common terminal m1 will be described.

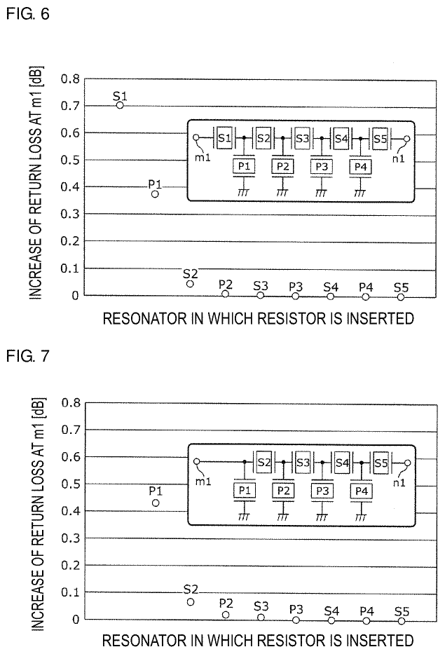

FIG. 6 is a diagram showing exemplary return loss of a first filter. In FIG. 6, description will be provided by taking, as an example, the first filter 10a of the example of the related art. FIG. 6 is a diagram showing an increase in return loss when a provided frequency signal is input with a resistor inserted to one of the resonators of the first filter 10a, relative to the return loss when the provided frequency signal is input to the first filter 10a from the common terminal m1 side. The provided frequency signal which is input to the first filter 10a is a signal including a frequency in the pass band (third frequency band) of the third filter 30.

As shown in FIG. 6, the return loss of the first filter 10a increases at a different rate depending on which resonator the resistor is provided in. The return loss indicates reflection loss of the first filter 10a provided when viewed from the common terminal m1. The larger the return loss is, the smaller the reflection of a signal from the first filter 10a is. That is, a frequency signal in the pass band of the third filter 30 is absorbed into the first filter 10a. Thus, the insertion loss in the third filter 30 increases.

As shown in FIG. 6, the increase in return loss provided when a resistor is inserted to the serial arm resonator S1 which is the closest to the common terminal m1 is about 0.7 dB; the increase in return loss provided when a resistor is inserted to the parallel arm resonator P1 which is the second closest is about 0.38 dB. In contrast, the increase in return loss provided when a resistor is inserted to the serial arm resonator S2 which is the third closest is about 0.05 dB; the increase in return loss provided when a resistor is inserted to each of the resonators P2 to P4 and S3 to S5 which are the fourth closest and its subsequent ones is about 0 dB, which may be considered as almost no increase in return loss.

In FIG. 6, description is provided by taking, as an example, the first filter 10a including a ladder topology, starting from the serial arm resonator S1 when viewed from the common terminal m1. A similar tendency is provided if the serial arm resonator S1 is not included.

FIG. 7 is a diagram showing other exemplary return loss of a first filter. In FIG. 7, description will be provided by taking, as an example, a filter including a ladder topology in which the serial arm resonator S1 is removed from the first filter 10a of the example of the related art, and in which the parallel arm resonator P1 and the serial arm resonator S2 are the first resonators when viewed from the common terminal m1. As in FIG. 6, FIG. 7 is a diagram showing an increase of return loss when a provided frequency signal is input with a resister inserted to one of the resonators of the first filter, relative to the return loss when the provided frequency signal (a signal including a frequency in the third frequency band) is input to the first filter from the common terminal m1 side.

As shown in FIG. 7, the increase in return loss provided when a resistor is inserted to the parallel arm resonator P1 closest to the common terminal m1 is about 0.43 dB; the increase in return loss provided when a resister is inserted to the serial arm resonator S2 which is also closest is about 0.08 dB. The increases in return loss provided when resisters are inserted to the respective resonators P2 to P4 and S3 to S5 which are the third closest and its subsequent resonators are about 0 dB, which may be considered as almost no increase in return loss.

Thus, as a resistor is included in a resonator closer to the common terminal m1, the return loss in the first filter increases. Particularly, in comparison among the parallel arm resonators P1 to P4, the increase in return loss in the first filter is the largest when a resister is included in the parallel arm resonator P1 connected at the position closest to the common terminal m1. Therefore, to reduce the insertion loss in the third filter 30, it is effective to take measures not to increase the resistance in the parallel arm circuit connected at the position closest to the common terminal m1.

Thus, as shown in FIG. 2, in the multiplexer 1 according to the present preferred embodiment, the parallel arm circuit 11, which is connected at the position closest to the common terminal m1 among the parallel arm circuits 11 to 14, does not include the parallel arm resonator Pa which causes an increase in return loss in the first filter 10, and in which at least one (in this example, the parallel arm circuit 12) of the parallel arm circuit 12 to 14 except the parallel arm circuit 11 includes the parallel arm resonator Pa.

### 4. Comparison Between the Example of the Related Art and the Embodiment Example

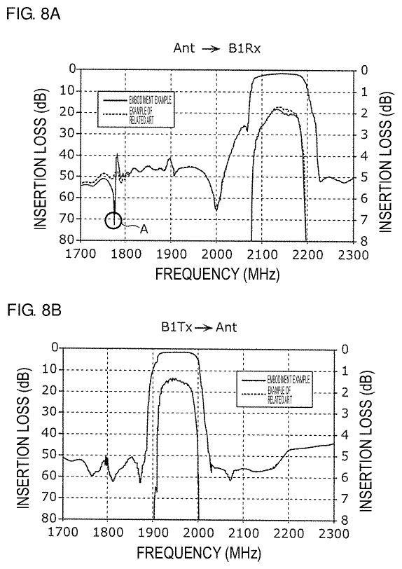

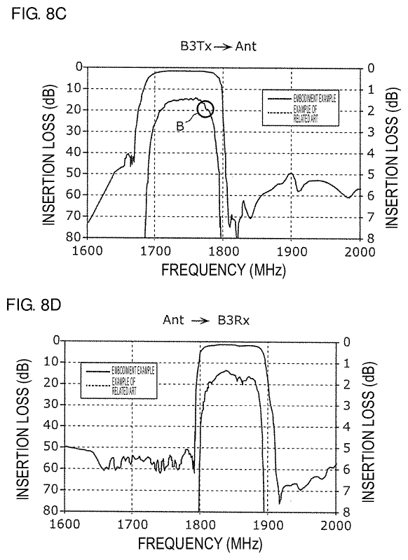

The fact that the problem (degradation in insertion loss of the third filter 30) which is present in the comparative example has been addressed will be described by comparing the example of the related art with the preferred embodiment example, as shown in FIGS. 8A to 8D.

FIG. 8A is a graph showing bandpass characteristics of the first filters 10 and 10a of the preferred embodiment example and the example of the related art. FIG. 8B is a graph showing bandpass characteristics of the second filters 20 of the preferred embodiment example and the example of the related art. FIG. 8C is a graph showing bandpass characteristics of the third filters 30 of the preferred embodiment example and the example of the related art. FIG. 8D is a graph showing bandpass characteristics of the fourth filters 40 of the preferred embodiment example and the example of the related art. FIGS. 8A to 8D show the bandpass characteristics of the preferred embodiment example with solid lines, and show the bandpass characteristics of the example of the related art with broken lines.

FIG. 8A shows bandpass characteristics in and around the first frequency band (Band1Rx: about 2110 MHz-about 2170 MHz) as bandpass characteristics of the first filter 10 of the preferred embodiment example and the first filter 10a of the example of the related art. FIG. 8A shows that, in portion A shown in FIG. 8A, the insertion loss of the preferred embodiment example is larger than that of the example of the related art. As described above, this occurs due to the influence of the parallel arm resonator Pa, whose resonant frequency is equal or substantially equal to the frequency, ±M×f1±N×f2 (for example, 2×f2−f1), of the interfering waves, that attenuates the interfering waves.

FIG. 8B shows bandpass characteristics in and around the second frequency band (Band1Tx: about 1920 MHz-about 1980 MHz) as bandpass characteristics of the second filters 20. FIG. 8B shows that there is no difference in the bandpass characteristics of the second filter 20 between the preferred embodiment example and the example of the related art.

FIG. 8C shows bandpass characteristics in and around the third frequency band (Band3Tx: about 1710 MHz-about 1785 MHz) as bandpass characteristics of the third filters 30. FIG. 8C shows that, while, in portion B shown in FIG. 5C, the insertion loss in the comparative example is degraded compared with the example of the related art, in portion B shown in FIG. 8C, no change in the insertion loss occurs between the example of the related art and the preferred embodiment example. In the comparative example, the parallel arm resonator Pa is included in the parallel arm circuit 11a connected at the position closest to the common terminal m1. An increase in resistance in the parallel arm circuit 11a due to the parallel arm resonator Pa increases the return loss of the first filter 10b. In contrast, in the preferred embodiment example, the parallel arm resonator Pa is not included in the parallel arm circuit 11 connected at the position closest to the common terminal m1. The resistance of the parallel arm circuit 11 is not increased, causing an increase in return loss of the first filter 10 to be significantly reduced or prevented.

FIG. 8D shows bandpass characteristics in and around the fourth frequency band (Band3Rx: about 1805 MHz-about 1880 MHz) as bandpass characteristics of the fourth filters 40. FIG. 8D shows that there is no or very little difference in the bandpass characteristics of the fourth filter 40 between the preferred embodiment example and the example of the related art.

Thus, degradation in insertion loss of the third filter 30 is significantly reduced or prevented in the preferred embodiment example.

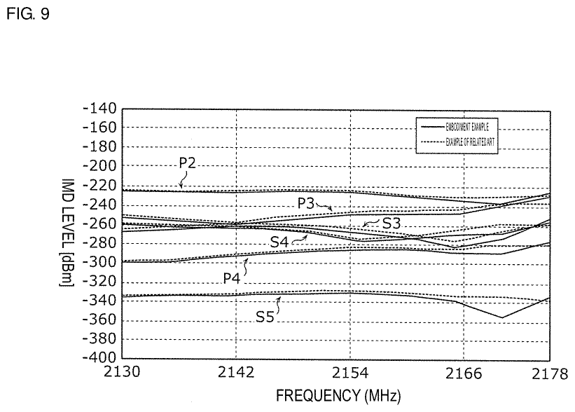

The IMD characteristics of the first filter if the parallel arm resonator Pa is included in the parallel arm circuit connected at the position second closest to the common terminal m1 (the preferred embodiment example), and the IMD characteristics of the first filter if the parallel arm resonator Pa is not included in any circuit (the example of the related art) will be described with respect to FIG. 9.

FIG. 9 is a diagram showing the IMD characteristics of the resonators in the first filters of the preferred embodiment example and the example of the related art. FIG. 9 shows simulation results of the IMD characteristics of the parallel arm resonators P2 to P4 and the serial arm resonators S3 to S5 which are present after the parallel arm circuit 12, in which the parallel arm resonator Pa is connected, when viewed from the common terminal m1. FIG. 9 shows the IMD characteristics of the preferred embodiment example with solid lines, and shows the IMD characteristics of the example of the related art with broken lines.

FIG. 9 shows that, in the preferred embodiment example, the IMDs of the resonators after the parallel arm circuit 12, in which the parallel arm resonator Pa is included, are reduced compared with those of the example of the related art. That is, even if, as in the comparative example, the parallel arm resonator Pa is included in the parallel arm circuit 11 connected at the position closest to the common terminal m1 is not employed, the parallel arm resonator Pa included in at least one (in this example, the parallel arm circuit 12) of the parallel arm circuits except the parallel arm circuit 11 may cause the IMD to be reduced.

In the preferred embodiment example, the parallel arm resonator Pa is included in the parallel arm circuit 12 connected at the position second closest to the common terminal m1. As the parallel arm resonator Pa is included in a parallel arm circuit connected farther from the common terminal m1, the number of resonators whose IMD is reduced is decreased, causing the effect of the reduction in the IMD to be weakened. For example, if the parallel arm resonator Pa is included in the parallel arm circuit 13 connected at the position third closest to the common terminal m1, it is difficult to reduce the IMD at the serial arm resonator S3 and the parallel arm resonator P2 compared with the preferred embodiment example as described above. Thus, the parallel arm resonator Pa is included in the parallel arm circuit 12, which is connected at the position closest to the common terminal m1 among the parallel arm circuits except the parallel arm circuit 11 connected at the position closest to the common terminal m1. Accordingly, the IMD in as many resonators as possible is able to be reduced, and thus the IMD is able to be reduced effectively.

As described above, in the first filter 10, the parallel arm resonator Pa is included in at least one (in this example, the parallel arm circuit 12) of the parallel arm circuits 11 to 14 except the parallel arm circuit 11 which is connected at the position closest to the common terminal m1. This causes the return loss of the first filter 10 to not be substantially affected, thus providing significant reduction or prevention of degradation of the insertion loss in the pass band of the third filter 30 connected to the first filter 10 through a common connection. The third frequency band includes a frequency of interfering waves, ±M×f1±N×f2, and the resonant frequency of the parallel arm resonator Pa is included in the third frequency band. Thus, the resonant frequency of the parallel arm resonator Pa may match any frequency expressed by ±M×f1±N×f2, and the parallel arm resonator Pa is able to attenuate the interfering waves. The first filter 10, which includes the parallel arm resonator Pa, may reduce the IMD. Therefore, while the IMD in the pass band of a receive filter (the first filter 10) is reduced, degradation of the insertion loss in the pass band of a different filter (the third filter 30) connected to the first filter 10 through a common connection may be significantly reduced or prevented.

Specifically, the resonant frequency of the parallel arm resonator Pa is at least one of the frequencies specifically expressed by ±M×f1±N×f2. Thus, the parallel arm resonator Pa may attenuate the interfering waves whose frequency is ±M×f1±N×f2.

Specifically, the parallel arm resonator Pa is included in the parallel arm circuit 12, which is connected at the position second closest to the common terminal m1, as a parallel arm circuit other than the parallel arm circuit 11. Accordingly, the IMD in the serial arm resonators S3 to S5 and the parallel arm circuits 12 to 14 (parallel arm resonators P2 to P4), which are connected after the parallel arm circuit 12 when viewed from the common terminal m1, is able to be reduced (that is, the IMD in as many resonators as possible is able to be reduced), thereby providing effective reduction of the IMD in the pass band of the receive filter.

The multiplexer 1 provided by the present invention is described with reference to preferred embodiments. The present invention is not limited to the preferred embodiments described above. The present invention also encompasses different preferred embodiments implemented by combining any components in the preferred embodiments with each other, a modified example provided by applying various changes, which are conceived by those skilled in the art, on the preferred embodiment without departing from the gist of the present invention, and various devices including the multiplexer 1 provided by the present invention.

For example, the multiplexer 1 of the preferred embodiment described above is a quadplexer including the first filter 10 to the fourth filter 40. Any circuit topology may be employed as long as the multiplexer 1 includes at least three filters, the first filter 10 to the third filter 30. For example, the multiplexer 1 may be a triplexer including the first filter 10 to the third filter 30. As long as the multiplexer 1 includes at least the three filters, the first filter 10 to the third filter 30, the multiplexer 1 may include five or more filters.

For example, in the preferred embodiment described above, the first filter 10 includes five serial arm resonators. The first filter 10 may have any circuit topology as long as the first filter 10 has at least one serial arm resonator. The first filter 10 includes four parallel arm circuits. The first filter 10 may have any circuit topology as long as the first filter 10 includes at least two parallel arm circuits.

For example, in the preferred embodiment described above, the parallel arm resonator Pa is included in the parallel arm circuit 12 connected at the position second closest to the common terminal m1. Alternatively, the parallel arm resonator Pa may be included in any parallel arm circuit as long as the parallel arm circuit is other than the parallel arm circuit 11 connected at the position closest to the common terminal m1. The parallel arm resonator Pa may be included in multiple parallel arm circuits as long as the parallel arm circuits are other than the parallel arm circuit 11 connected at the position closest to the common terminal m1.

For example, in the preferred embodiment described above, the parallel arm circuit including the parallel arm resonator Pa includes a different parallel arm resonator (for example, the parallel arm resonator P2). The parallel arm circuit may include no other parallel arm resonators except the parallel arm resonator Pa. That is, for example, the parallel arm circuit 12 may include only the parallel arm resonator Pa.

For example, in the preferred embodiment described above, the first frequency band is about 2110 MHz to about 2170 MHz; the second frequency band is about 1920 MHz to about 1980 MHz; the third frequency band is about 1710 MHz to about 1785 MHz. However, this is not limiting. For example, when the frequency in the first frequency band is referred to as f1 and the frequency in the second frequency band is referred to as f2, if at least one of the frequencies expressed by ±M×f1±N×f2 is included in the third frequency band, a different set of frequency bands may be implemented. For example, a combination of the first frequency band, the second frequency band, and the third frequency band may be a combination of Band3Rx (about 1805 MHz-about 1880 MHz), Band5Tx (about 824 MHz-about 849 MHz), and Band5Rx (about 869 MHz-about 894 MHz). Accordingly, f1-f2 is included in the third frequency band. Alternatively, for example, a combination of the first frequency band, the second frequency band, and the third frequency band may be a combination of Band7Tx (about 2500 MHz-about 2570 MHz), Band20Tx (about 832 MHz-about 862 MHz), and Band20Rx (about 791 MHz-about 821 MHz). Accordingly, f1−2×f2 is included in the third frequency band.

For example, in the preferred embodiment described above, the first filter 10 includes the ladder circuit. Alternatively, the first filter 10 may be provided by combining a ladder circuit with a longitudinally-coupled filter.

For example, in the preferred embodiment described above, the resonant frequency of the parallel arm resonator Pa is the same or substantially the same as one of the frequencies expressed by ±M×f1±N×xf2. As long as the resonant frequency is in a frequency range expressed by ±M×f1±N×f2, if the difference between the resonant frequency and any frequency expressed by ±M×f1±N×f2 is small, this hardly causes a problem in view of the characteristics of the multiplexer 1.

Preferred embodiments of the present invention may be implemented widely as a multiplexer, which may be applied to a multi-band system, in communication devices, for example, cellular phones.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A multiplexer comprising:
a common terminal, a first terminal, a second terminal, and a third terminal;
a first filter that is a receive filter on a first path electrically connecting the common terminal to the first terminal and that uses an acoustic wave whose pass band is a first frequency band;
a second filter on a second path electrically connecting the common terminal to the second terminal and having a pass band which is a second frequency band; and
a third filter on a third path electrically connecting the common terminal to the third terminal and having a pass band which is a third frequency band; wherein
the first frequency band, the second frequency band, and the third frequency band are bands whose center frequencies are different from each other;
the first filter includes a ladder circuit including at least one serial arm resonator on the first path and a plurality of parallel arm circuits between a ground and corresponding connection nodes which are provided on the first path and which are different from each other;
at least one of the plurality of parallel arm circuits except a closest parallel arm circuit includes a first parallel arm resonator, the closest parallel arm circuit being connected at a position closest to the common terminal; and
at least one of frequencies expressed by ±M×f1±N×f2 is included in the third frequency band where N and M are natural numbers equal to or more than one, f1 represents a frequency included in the first frequency band, and f2 represents a frequency included in the second frequency band, and a resonant frequency of the first parallel arm resonator is included in the third frequency band.

2. The multiplexer according to claim 1, wherein the resonant frequency of the first parallel arm resonator is at least one of the frequencies expressed by ±M×f1±N×f2.

3. The multiplexer according to claim 1, wherein the first parallel arm resonator is included in a parallel arm circuit connected at a position second closest to the common terminal among the plurality of parallel arm circuits.

4. The multiplexer according to claim 1, wherein
the second filter is a transmit filter; and
the first filter and the second filter define a duplexer.

5. The multiplexer according to claim 1, wherein:
the first frequency band is between about 2110 MHz and about 2170 MHz,
the second frequency band is between about 1920 MHz and about 1980 MHz, and
the third frequency band is between about 1710 MHz and about 1785 MHz.

6. The multiplexer according to claim 1, wherein the third filter is a transmit filter.

7. The multiplexer according to claim 1, further comprising:
a fourth terminal; and
a fourth filter on a fourth path electrically connecting the common terminal to the fourth terminal and having a pass band which is a fourth frequency band.

8. The multiplexer according to claim 7, wherein the fourth frequency band is between about 1805 MHz and about 1880 MHz.

9. The multiplexer according to claim 7, wherein the fourth filter is a receive filter.

10. The multiplexer according to claim 7, wherein the first filter, the second filter, the third filter, and the fourth filter define a quadplexer.

11. The multiplexer according to claim 1, wherein the first filter further includes at least two parallel arm circuits provided between the ground and a same connection node.

12. The multiplexer according to claim 1, wherein each of the plurality of parallel arm circuits includes a resonator or an impedance element.

13. The multiplexer according to claim 1, wherein each of the at least one serial arm resonator and each of the plurality of parallel arm circuits is an acoustic wave resonator.

14. The multiplexer according to claim 1, wherein the first filter includes interdigital transducer electrodes provided on a piezoelectric substrate.

15. The multiplexer according to claim 13, wherein the piezoelectric substrate includes a piezoelectric thin film and a multilayer body that includes a film having an acoustic velocity different from an acoustic velocity of the piezoelectric thin film.
